(19) United States
(12) Patent Application Publication
(10) Pub. No.: US 2026/0314299 A1
(43) Pub. Date: Oct. 8, 2026

(54) METHOD FOR FABRICATING A SEMICONDUCTOR DEVICE USING HEAT TREATMENT APPARATUS

(71) Applicant: SAMSUNG ELECTRONICS CO., LTD., Suwon-si (KR)

(72) Inventors: Woo-Seok SHIM, Suwon-si (KR); Kyo Il KOO, Suwon-si (KR)

(73) Assignee: SAMSUNG ELECTRONICS CO., LTD., Suwon-si (KR)

(21) Appl. No.: 19/393,059

(22) Filed: Nov. 18, 2025

(30) Foreign Application Priority Data
Apr. 4, 2025 (KR) 10-2025-0044187

(51) Int. Cl. H10P 72/00; H10P 74/00

(52) U.S. Cl. CPC H10P 72/0436; H10P 72/0616; H10P 74/238

(57) ABSTRACT

A method for fabricating a semiconductor device includes obtaining measurement information by measuring a warpage of a wafer, forming a warpage control layer entirely on a lower surface of the wafer, adjusting either a type of a shutter or a size of an open region of the shutter using the measurement information, the shutter positioned below the wafer inside a chamber, providing to the warpage control layer a light emitted from a light source and passing through the shutter, and adjusting the warpage by partially changing a temperature of the warpage control layer using the light provided to the warpage control layer, wherein the shutter is positioned between the light source and the lower surface of the wafer, and wherein the lower surface of the wafer and a lower surface of the warpage control layer are spaced apart from an upper surface of the shutter in a vertical direction.

### CROSS-REFERENCE TO RELATED APPLICATION

This application claims priority from Korean Patent Application No. 10-2025-0044187 filed on Apr. 4, 2025 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a method for fabricating a semiconductor device using a heat treatment apparatus.

### 2. Description of the Related Art

With advances in electronic technology, the down-scaling of semiconductor devices has rapidly progressed, leading to growing demands for higher integration and lower power consumption of semiconductor devices. Recently, semiconductor devices with vertical structures (e.g., DRAM or NAND) have been developed to achieve high integration of semiconductor devices.

However, during the wafer stage of fabricating semiconductor devices with vertical structures, a warpage issue in which the wafer is bent due to stress differences between adjacent material layers has arisen. When warpage occurs on a wafer, it may cause issues such as chucking failure, misalignment between adjacent layers, crack formation, and poor contact during the packaging stage. As a result, research is being conducted to reduce wafer warpage.

### SUMMARY

An object of the present disclosure is to provide a method for fabricating a semiconductor device that reduces wafer warpage and improves the reliability of the fabrication process.

The aspects of the present disclosure are not limited to those described above, and other aspects not explicitly mentioned may be clearly understood by those skilled in the art from the following description.

According to some embodiments of the present disclosure, there is provided a method for fabricating a semiconductor device, comprising obtaining a warpage measurement information by measuring a warpage of a wafer, forming a warpage control layer entirely on a lower surface of the wafer, adjusting either a type of a shutter or a size of an open region of the shutter using the warpage measurement information, the shutter positioned below the wafer inside a chamber, providing to the warpage control layer a light that is emitted from a light source and passes through the shutter, and adjusting the warpage of the wafer by partially changing a temperature of the warpage control layer using the light provided to the warpage control layer, wherein the shutter is positioned between the light source and the lower surface of the wafer, and wherein each of the lower surface of the wafer and a lower surface of the warpage control layer is spaced apart from an upper surface of the shutter in a vertical direction.

According to some embodiments of the present disclosure, there is provided a method for fabricating a semiconductor device, comprising forming a warpage control layer entirely on a lower surface of a wafer having a warpage, adjusting a size of an open region of a shutter in a first horizontal direction parallel to an upper surface of the shutter, the shutter positioned below the wafer inside a chamber, providing to the warpage control layer a light that is emitted from a light source and passes through the shutter, adjusting the warpage of the wafer by partially changing a temperature of the warpage control layer using the light provided to the warpage control layer, determining whether the warpage of the wafer is within a predetermined range while the warpage of the wafer is being adjusted, and stopping the emission of the light from the light source when the warpage of the wafer is within the predetermined range, wherein the shutter is positioned between the light source and the lower surface of the wafer.

According to some embodiments of the present disclosure, there is provided a method for fabricating a semiconductor device, comprising obtaining a warpage measurement information by measuring a warpage of a wafer, loading the wafer having the warpage into a chamber, forming a warpage control layer entirely on a lower surface of the wafer inside the chamber, adjusting a size of an open region of a shutter in a first horizontal direction parallel to an upper surface of the shutter using the warpage measurement information, the shutter positioned below the wafer inside the chamber, providing to the warpage control layer a light that is emitted from a light source and passes through the shutter, adjusting the warpage of the wafer by partially changing a temperature of the warpage control layer using the light provided to the warpage control layer, determining whether the warpage of the wafer is within a predetermined range while the warpage is being adjusted, and stopping the emission of the light from the light source when the warpage of the wafer is within the predetermined range, wherein the shutter is positioned between the light source and the lower surface of the wafer, wherein each of the lower surface of the wafer and a lower surface of the warpage control layer is spaced apart from the upper surface of the shutter in a vertical direction, and wherein the open region extends in a second horizontal direction parallel to the upper surface of the shutter, and the second horizontal direction is perpendicular to the first horizontal direction.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a schematic diagram for explaining a heat treatment apparatus used in a method for fabricating a semiconductor device according to some embodiments of the present disclosure;

FIGS. 2 and 3 are diagrams for explaining a shutter of the heat treatment apparatus according to some embodiments of the present disclosure;

FIG. 4 is a flow chart for explaining a method for fabricating a semiconductor device according to some embodiments of the present disclosure;

FIGS. 5, 6 and 7 are diagrams for explaining the control of the wafer warpage in the method for fabricating a semiconductor device according to some embodiments of the present disclosure;

FIG. 8 is a flow chart for explaining a method for fabricating a semiconductor device according to some other embodiments of the present disclosure;

FIGS. 9 and 10 are diagrams for explaining a shutter of the heat treatment apparatus according to still other embodiments of the present disclosure;

FIGS. 11, 12, 13, 14 and 15 are diagrams for explaining a shutter of the heat treatment apparatus according to yet other embodiments of the present disclosure;

FIGS. 16 and 17 are diagrams for explaining a shutter of the heat treatment apparatus according to further embodiments of the present disclosure; and

FIG. 18 is a diagram for explaining a shutter of the heat treatment apparatus according to further embodiments of the present disclosure.

### DETAILED DESCRIPTION OF THE EMBODIMENTS

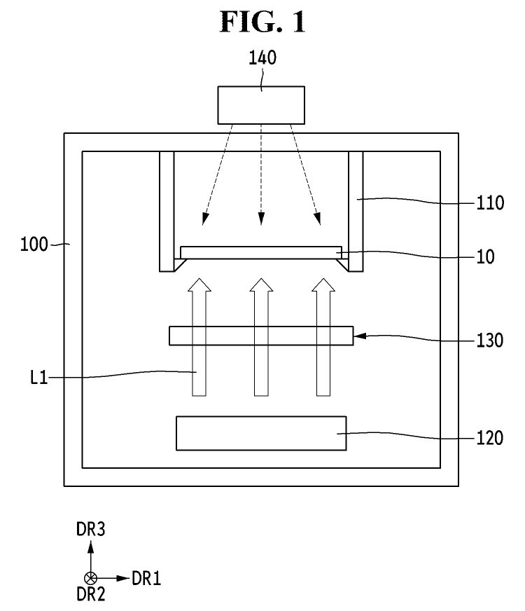

Hereinafter, a heat treatment apparatus used in a method for fabricating a semiconductor device according to some embodiments of the present disclosure will be described with reference to FIGS. 1 to 3.

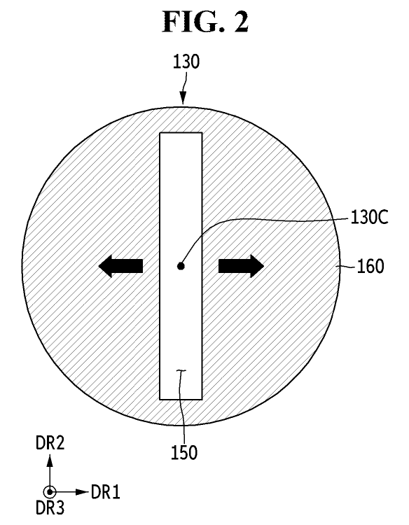

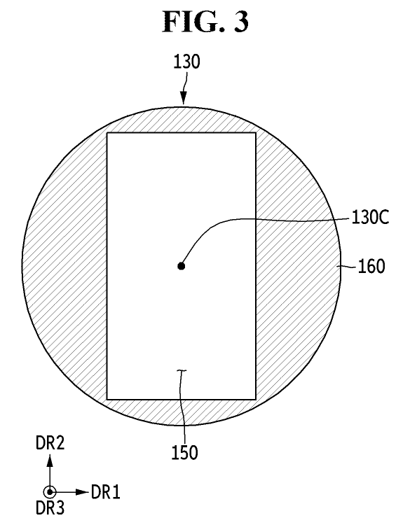

FIG. 1 is a schematic diagram for explaining a heat treatment apparatus used in a method for fabricating a semiconductor device according to some embodiments of the present disclosure. FIGS. 2 and 3 are diagrams for explaining a shutter of a heat treatment apparatus according to some embodiments of the present disclosure.

Referring to FIGS. 1 to 3, the heat treatment apparatus used in a method for fabricating a semiconductor device according to some embodiments of the present disclosure includes a chamber 100, a wafer support 110, a light source 120, a shutter 130, and a warpage measurement unit 140. The heat treatment apparatus described below is an apparatus that performs an annealing process to heat a wafer 10.

The chamber 100 may function as a housing that accommodates the other components inside. The chamber 100 may be a kind of isolated space in which the annealing process is performed on the wafer 10. In some embodiments, both the annealing process and the process of forming a warpage control layer 20 may be performed inside the chamber 100. In other embodiments, only the annealing process may be performed inside the chamber 100. For example, the wafer 10 may include a plurality of semiconductor devices before a sawing process is performed.

The wafer support 110 may be positioned inside the chamber 100. For example, the wafer support 110 may extend from an upper inner wall of the chamber 100 toward the inside of the chamber 100. The wafer support 110 may hold the wafer 10 loaded into the chamber 100. That is, the wafer 10 may be supported by the wafer support 110 inside the chamber 100. For instance, the wafer support 110 may be positioned along a sidewall of the wafer 10. For example, at least a portion of the wafer support 110 may be positioned under the lower surface of the wafer 10 to provide support. The shape of the wafer support 110 shown in FIG. 1 is exemplary, and the present disclosure is not limited thereto.

The shutter 130 may be positioned inside the chamber 100. The shutter 130 may be positioned below the wafer 10. Hereinafter, a first horizontal direction DR1 and a second horizontal direction DR2 may be defined as directions parallel to the upper surface of the shutter 130. The second horizontal direction DR2 may be defined as a direction perpendicular to the first horizontal direction DR1. A vertical direction DR3 may be defined as being perpendicular to both the first horizontal direction DR1 and the second horizontal direction DR2. That is, the vertical direction DR3 may be defined as a direction perpendicular to the upper surface of the shutter 130.

For example, in a plane defined by the first horizontal direction DR1 and the second horizontal direction DR2, the shutter 130 may have the shape of a circular flat plate. However, the present disclosure is not limited thereto. In some other embodiments, the shutter 130 may have a non-circular plate shape in the plane defined by the first horizontal direction DR1 and the second horizontal direction DR2. For example, the lower surface of the wafer 10 may be spaced apart from the upper surface of the shutter 130 in the vertical direction DR3. The shutter 130 may overlap the wafer 10 in the vertical direction DR3.

For example, the shutter 130 may include an open region 150 and a non-open region 160. The open region 150 may be defined as the region that penetrates the shutter 130 from a lower surface of the shutter to an upper surface of the shutter 130 in the vertical direction DR3. The non-open region 160 may be defined as the remaining region of the shutter 130 excluding the open region 150. For example, the open region 150 of the shutter 130 may extend in the second horizontal direction DR2. For example, the open region 150 of the shutter 130 may pass through the center 130C of the shutter 130 and extend in the second horizontal direction DR2.

For example, the size of the open region 150 of the shutter 130 may be adjusted in the first horizontal direction DR1. For example, a width of the open region 150 of the shutter 130 in the first horizontal direction DR1 may be adjustable. In some embodiments, the width of the open region 150 of the shutter 130 in the second horizontal direction DR2 may be fixed. In other embodiments, the width of the open region 150 of the shutter 130 in the second horizontal direction DR2 may also be adjustable. FIGS. 2 and 3 show the operation of the shutter 130. For example, FIG. 2 shows a state in which the width of the open region 150 of the shutter 130 in the first horizontal direction DR1 is reduced. FIG. 3 shows a state in which the width of the open region 150 of the shutter 130 in the first horizontal direction DR1 is increased. That is, as shown in FIGS. 2 and 3, the size of the open region 150 of the shutter 130 may be adjustable in the first horizontal direction DR1.

For example, the shutter 130 may include a heat-dissipating material. In some embodiments, the shutter 130 may include stainless steel or a thin carbon film. However, the present disclosure is not limited thereto. In other embodiments, the shutter 130 may include a material that transmits a portion of light. For example, the shutter 130 may include quartz or glass. However, the present disclosure is not limited thereto.

The light source 120 may be positioned inside the chamber 100. However, the present disclosure is not limited thereto. In some other embodiments, the light source 120 may be positioned outside the chamber 100. The light source 120 may be positioned below the shutter 130. That is, the shutter 130 may be positioned between the light source 120 and the wafer 10. For example, the lower surface of the shutter 130 may be spaced apart from the light source 120 in the vertical direction DR3. The light source 120 may emit light L1 to heat the wafer 10. For example, the light L1 emitted from the light source 120 may pass through the shutter 130 and be provided to a warpage control layer 20 formed on the lower surface of the wafer 10.

In some embodiments, when the shutter 130 includes a material that does not transmit the light L1, the light L1 emitted from the light source 120 may pass through the open region 150 of the shutter 130 and be provided to the warpage control layer 20 formed on the lower surface of the wafer 10.In other embodiments, when the shutter 130 includes a material that transmits a portion of the light L1, the light L1 emitted from the light source 120 may pass through both the open region 150 and the non-open region 160 of the shutter 130 and be provided to the warpage control layer 20 formed on the lower surface of the wafer 10.

For example, the warpage control layer 20 may be entirely formed on the lower surface of the wafer 10. In other words, the warpage control layer 20 may entirely cover the lower surface of the wafer 10. For example, the lower surface of the warpage control layer 20 may be spaced apart from the upper surface of the shutter 130 in the vertical direction DR3. For example, the warpage control layer 20 may include an insulating material. For example, the warpage control layer 20 may include silicon oxide (SiO₂) or silicon nitride (SiN). However, the present disclosure is not limited thereto. In some embodiments, the warpage control layer 20 may include a material that expands in volume upon receiving light L1. However, the present disclosure is not limited thereto. In some other embodiments, the warpage control layer 20 may also include a material that expands in volume upon receiving light L1. Hereinafter, a description will be provided based on embodiments in which the warpage control layer 20 includes a material that expands in volume upon receiving light L1.

The warpage measurement unit 140 may measure the warpage of the wafer 10 loaded into the chamber 100. In FIG. 1, the warpage measurement unit 140 is shown to be positioned above the chamber 100, but this is exemplary and the position of the warpage measurement unit 140 is not limited thereto.

Hereinafter, with reference to FIGS. 1 and 4 through 7, a method for fabricating a semiconductor device according to some embodiments of the present disclosure will be described.

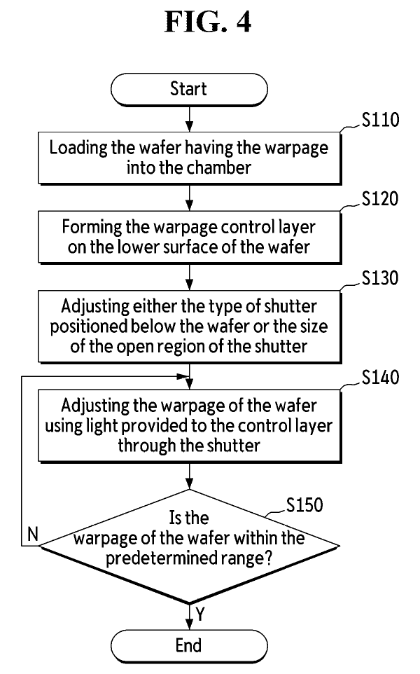

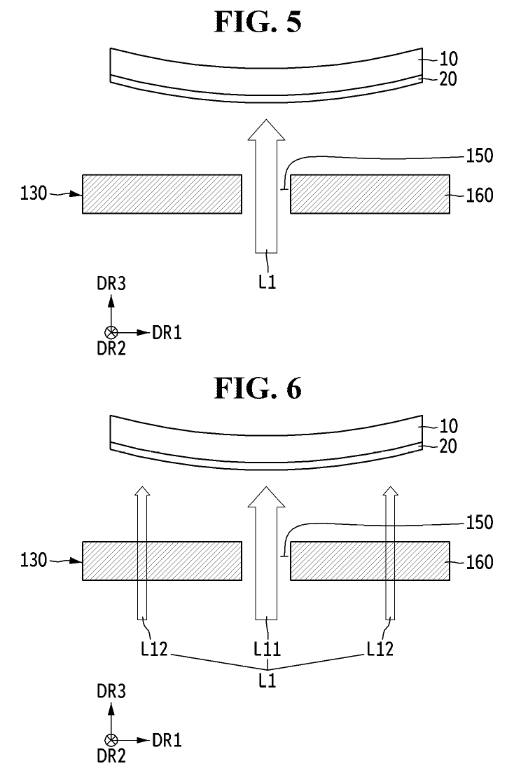

FIG. 4 is a flow chart for explaining a method for fabricating a semiconductor device according to some embodiments of the present disclosure. FIGS. 5, 6 and 7 are diagrams for explaining the process of adjusting the warpage of wafer in the method for fabricating a semiconductor device according to some embodiments of the present disclosure.

Referring to FIGS. 1 and 4 through 7, the warpage of the wafer 10 may be measured to obtain warpage measurement information. For example, the wafer 10 may include a plurality of semiconductor devices before a sawing process is performed. Subsequently, the wafer 10 having warpage may be loaded into the chamber 100 (S110). For example, the wafer 10 loaded into the chamber 100 may be held by a wafer support 110.

Next, the warpage control layer 20 may be formed on the lower surface of the wafer 10 inside the chamber 100 (S120). For example, the warpage control layer 20 may be entirely formed on the lower surface of the wafer 10. In other words, the warpage control layer 20 may entirely cover the lower surface of the wafer 10. For example, the warpage control layer 20 may be formed conformally. For example, the warpage control layer 20 may include an insulating material. For example, the warpage control layer 20 may include silicon oxide (SiO₂) or silicon nitride (SiN). However, the present disclosure is not limited thereto. In some embodiments, the warpage control layer 20 may include a material that expands in volume upon receiving light L1. In some other embodiments, the warpage control layer 20 may also include a material that shrinks in volume upon receiving light L1.

Subsequently, using the warpage measurement information, a type of the shutter 130, which is positioned below the wafer 10 inside the chamber 100, may be adjusted, or the size of an open region 150 of the shutter 130 may be adjusted (S130). For example, as shown in FIG. 5, when the warpage measurement information of the wafer 10 includes information that the central portion of the lower surface of the wafer 10 has a warpage that is convex toward the upper surface of the shutter 130, the shutter 130 shown in FIGS. 2 and 3 may be positioned between the light source 120 and the wafer 10. In other words, using the warpage measurement information of the wafer 10, a shutter 130 having a suitable shape of the open region 150 may be positioned between the light source 120 and the wafer 10. Additionally, the size of the open region 150 of the shutter 130 may be adjusted in consideration of the degree and area of warpage of the wafer 10. For example, the width of the open region 150 of the shutter 130 in a first horizontal direction DR1 may be adjusted in consideration of the degree and area of warpage of the wafer 10.

Subsequently, light L1 provided from the light source 120 may pass through the shutter 130 and be provided to the warpage control layer 20. The light L1 passing through the shutter 130 and being provided to the warpage control layer 20 may partially change the temperature of the warpage control layer 20 and thereby adjust the warpage of the wafer 10 (S140).

For example, when the shutter 130 includes a material that blocks light L1, as shown in FIG. 5, the light L1 may pass through the open region 150 of the shutter 130, and be provided to the warpage control layer 20 formed on the lower surface of the wafer 10. For example, the light L1 passing through the open region 150 of the shutter 130 may be provided to a portion of the warpage control layer 20, and the light L1 is not provided to the remaining portion of the warpage control layer 20 that overlaps the non-open region 160 of the shutter 130 in the vertical direction DR3. In other words, the light L1 passing through the open region 150 of the shutter 130 heats a portion of the warpage control layer 20, while the remaining portion of the warpage control layer 20 that overlaps the non-open region 160 in the vertical direction DR3, is not heated. As a result, a temperature difference may occur between the heated portion of the warpage control layer 20 and the remaining portion of the warpage control layer 20 that is not heated. This temperature difference may be used to adjust the warpage of the wafer 10.

For example, when the shutter 130 includes a material that transmits a portion of the light L1, as shown in FIG. 6, the light L1 may pass through both the open region 150 of the shutter 130 and the non-open region 160 of the shutter 130, respectively, to be provided to the warpage control layer 20 formed on the lower surface of the wafer 10. In this case, the light L1 may include a first light L11 that passes through the open region 150 of the shutter 130, and a second light L12 that has passed through the non-open region 160 of the shutter 130. The power of the second light L12 is less than the power of the first light L11.

For instance, the first light L11 that has passed through the open region 150 of the shutter 130 may be provided to a portion of the warpage control layer 20, while the second light L12 that has passed through the non-open region 160 of the shutter 130 may be provided to the remaining portion of the warpage control layer 20. That is, the first light L11 passing through the open region 150 of the shutter 130 may heat a portion of the warpage control layer 20 to a first temperature, and the second light L12 passing through the non-open region 160 of the shutter 130 may heat the remaining portion of the warpage control layer 20 to a second temperature lower than the first temperature. As a result, a temperature difference may occur between the portion of the warpage control layer 20 heated to the first temperature and the remaining portion heated to the second temperature. This temperature difference may be used to adjust the warpage of the wafer 10.

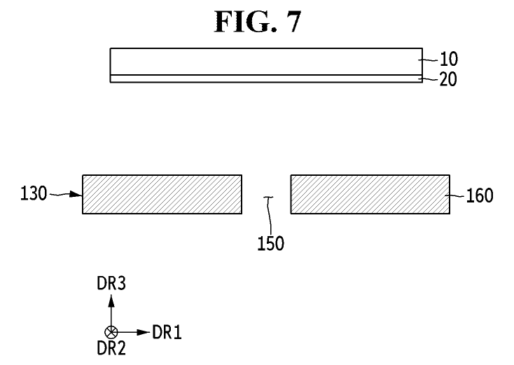

While the warpage of the wafer 10 is being adjusted using the light L1, the warpage measurement unit 140 may measure the warpage of the wafer 10. The warpage measurement unit 140 may determine whether the warpage of the wafer 10 is within a predetermined range (S150). For example, if the warpage of the wafer 10 is within the predetermined range, the emission of light L1 from the light source 120 may be stopped. That is, if the warpage of the wafer 10 is within the predetermined range, the annealing process for the wafer 10 may be stopped. For example, if the warpage of the wafer 10 is not within the predetermined range, the light L1 from the light source 120 may continue to be emitted. That is, if the warpage of the wafer 10 is not within the predetermined range, the annealing process for the wafer 10 may not be stopped. For example, the warpage of the wafer 10 after the annealing process for the wafer 10 is stopped may have a shape as shown in FIG. 7.

The method for fabricating a semiconductor device according to some embodiments of the present disclosure may include forming the warpage control layer 20 entirely on the lower surface of the wafer 10, partially changing the temperature of the warpage control layer 20 using a shutter 130 positioned below the wafer 10, and adjusting the warpage of the wafer 10 by using the partial temperature difference of the warpage control layer 20. Accordingly, the method for fabricating a semiconductor device according to some embodiments of the present disclosure may reduce the warpage of the wafer 10 and improve the reliability of the semiconductor device fabrication process.

Hereinafter, with reference to FIGS. 1 to 8, a method for fabricating a semiconductor device according to other embodiments of the present disclosure will be described. The description will focus on the differences from the method for fabricating a semiconductor device shown in FIG. 7.

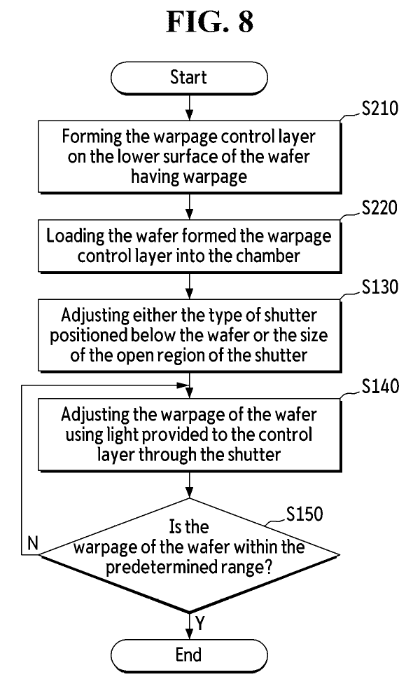

FIG. 8 is a flow chart for explaining a method for fabricating a semiconductor device according to other embodiments of the present disclosure.

Referring to FIGS. 1 and 8, the warpage of the wafer 10 may be measured to obtain warpage measurement information. For example, the wafer 10 may include a plurality of semiconductor devices before a sawing process is performed. Subsequently, a warpage control layer 20 (see FIGS. 5, 6 and 7) may be formed entirely on the lower surface of the wafer 10 where the warpage has formed (S210). For example, the warpage control layer 20 (see FIGS. 5, 6 and 7) may be formed outside the chamber 100. Next, the wafer 10 with the warpage control layer 20 (see FIGS. 5, 6 and 7) formed thereon may be loaded into the chamber 100 (S220). For example, the wafer 10 loaded into the chamber 100 may be held by a wafer support 110.

Subsequently, using the warpage measurement information, the shutter 130 positioned below the wafer 10 inside the chamber 100 may be replaced, or the size of an open region 150 of the shutter 130 may be adjusted (S130). Then, light L1 provided from the light source 120 may pass through the shutter 130 and be provided to the warpage control layer 20. The light L1 provided to the warpage control layer 20 through the shutter 130 may partially change the temperature of the warpage control layer 20 and adjust the warpage of the wafer 10 (S140). The warpage measurement unit 140 may determine whether the warpage of the wafer 10 is within a predetermined range (S150). For example, if the warpage of the wafer 10 is within the predetermined range, the annealing process for the wafer 10 may be stopped. On the other hand, if the warpage of the wafer 10 is not within the predetermined range, the annealing process for the wafer 10 may not be stopped.

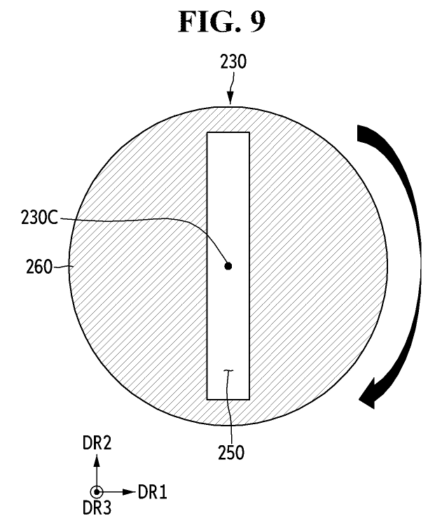

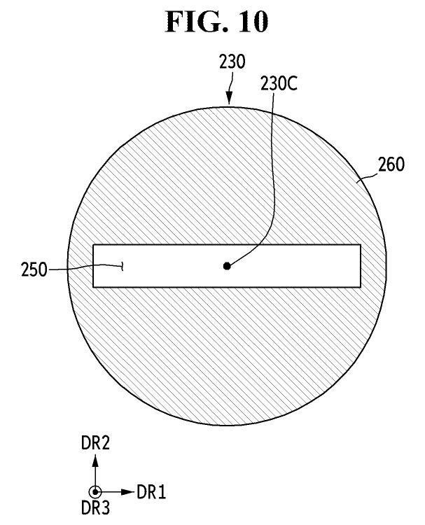

Hereinafter, a shutter of the heat treatment apparatus according to some other embodiments of the present disclosure will be described with reference to FIGS. 9 and 10. The description will focus on differences from the shutter of the heat treatment apparatus shown in FIGS. 2 and 3.

FIGS. 9 and 10 are diagrams for explaining a shutter of the heat treatment apparatus according to some other embodiments of the present disclosure.

Referring to FIGS. 9 and 10, a shutter 230 of the heat treatment apparatus according to some other embodiments of the present disclosure may be rotatable.

For example, the shutter 230 may rotate about the center 230C of the shutter 230 in a plane parallel to the upper surface of the shutter 230. That is, in a plane defined by the first horizontal direction DR1 and the second horizontal direction DR2, the shutter 230 may rotate about the center 230C of the shutter 230. For example, the shutter 230 may include an open region 250 and a non-open region 260. For example, as shown in FIG. 9, the open region 250 of the shutter 230 before rotation may extend in the second horizontal direction DR2. For example, as shown in FIG. 10, after rotation, the open region 250 of the shutter 230 may extend in the first horizontal direction DR1.

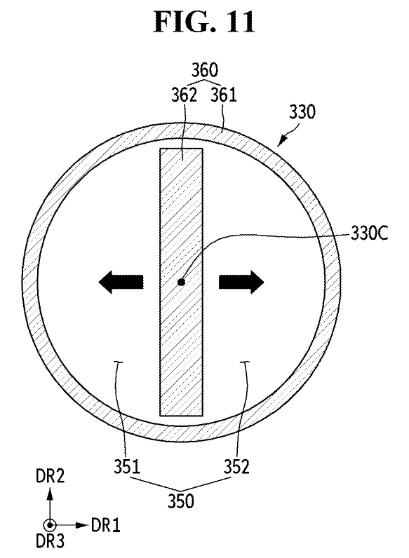

Hereinafter, with reference to FIGS. 11, 12, 13, 14 and 15, a shutter of the heat treatment apparatus according to some other embodiments of the present disclosure will be described. The description will focus on differences from the shutter of the heat treatment apparatus shown in FIGS. 2 and 3.

FIGS. 11 and 12, 13, 14 and 15 are diagrams for explaining a shutter of the heat treatment apparatus according to some other embodiments of the present disclosure.

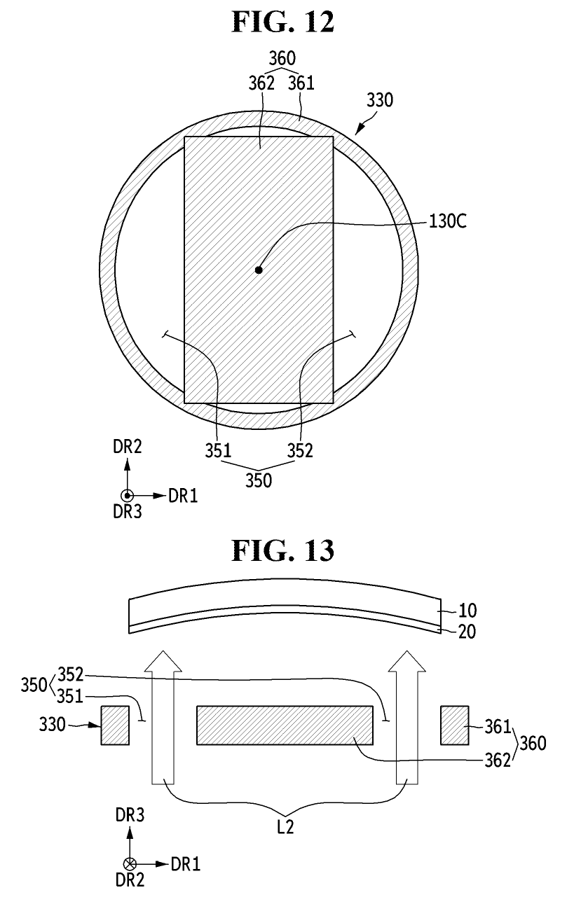

Referring to FIGS. 11 and 12, the shutter 330 of the heat treatment apparatus according to some other embodiments of the present disclosure may include an open region 350 and a non-open region 360. The open region 350 may include a first open region 351 and a second open region 352.

For example, the non-open region 360 of the shutter 330 may include a first portion 361 and a second portion 362. The first portion 361 of the non-open region 360 of the shutter 330 may form an outer edge of the shutter 330. For example, the first portion 361 of the non-open region 360 of the shutter 330 may have a ring shape. The second portion 362 of the non-open region 360 of the shutter 330 may be positioned between the first portions 361 of the non-open region 360 of the shutter 330. For example, the second portion 362 of the non-open region 360 of the shutter 330 may extend in the second horizontal direction DR2, passing through the center 330C of the shutter 330. In FIG. 11, the second portion 362 of the non-open region 360 of the shutter 330 is shown as being spaced apart from the first portion 361 of the non-open region 360 of the shutter 330 in the second horizontal direction DR2, but the technical idea of the present disclosure is not limited thereto.

For example, the first open region 351 may be defined as a region formed on a first side of the second portion 362 of the non-open region 360. The second open region 352 may be defined as a region formed on a second side of the second portion 362 of the non-open region 360, facing the first side of the second portion 362 of the non-open region 360 in the first horizontal direction DR1. For example, the size of each of the first open region 351 and the second open region 352 may be adjusted in the first horizontal direction DR1. FIGS. 11 and 12 show the operation of the shutter 330. For example, FIG. 11 shows a state in which the width of the first open region 351 in the first horizontal direction DR1 and the width of the second open region 352 in the first horizontal direction DR1 are each reduced. FIG. 12 shows a state in which the width of the first open region 351 in the first horizontal direction DR1 and the width of the second open region 352 in the first horizontal direction DR1 are each increased.

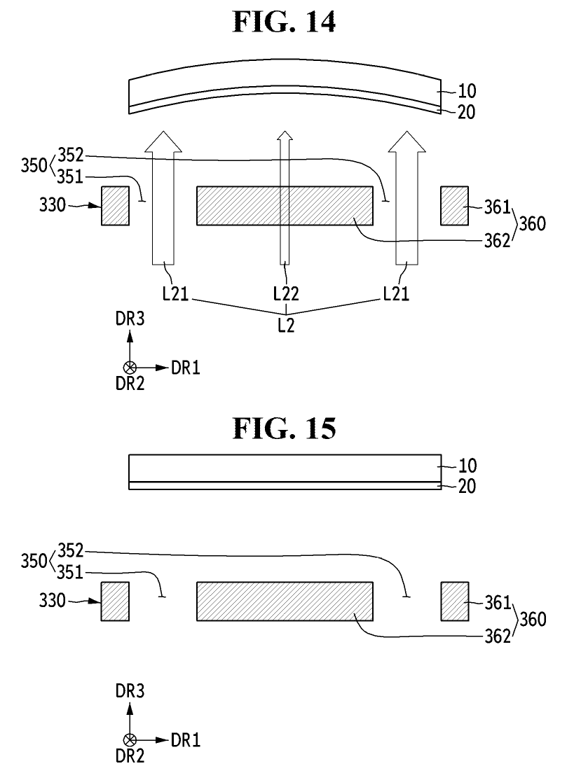

Referring to FIGS. 13 and 14, the wafer 10 may have a warpage formed so that the edge portion of the lower surface of the wafer 10 protrudes toward the upper surface of the shutter 330. For example, if the shutter 330 includes a material that does not transmit light L2, as shown in FIG. 13, light L2 may pass through the open region 350 of the shutter 330 and be provided to the warpage control layer 20 formed on the lower surface of the wafer 10. For example, the light L2 passing through the open region 350 of the shutter 330 may be provided to a portion of the warpage control layer 20, and light L2 may not be delivered to the remaining portion of the warpage control layer 20 that overlaps the non-open region 360 of the shutter 330 in the vertical direction DR3. In other words, the light L2 passing through the open region 350 of the shutter 330 heats a portion of the warpage control layer 20, while the remaining portion of the warpage control layer 20 that overlaps the non-open region 360 of the shutter 330 in the vertical direction DR3 is not heated. As a result, a temperature difference may occur between the heated portion of the warpage control layer 20 and the remaining portion of the warpage control layer 20 that is not heated. This temperature difference may be used to adjust the warpage of the wafer 10.

For example, if the shutter 330 includes a material that transmits a portion of the light L2, as shown in FIG. 14, the light L2 may pass through both the open region 350 of the shutter 330 and the non-open region 360 of the shutter 330 and be provided to the warpage control layer 20 formed on the lower surface of the wafer 10. In this case, the light L2 may include a first light L21 that has passed through the open region 350 of the shutter 330 and a second light L22 that has passed through the non-open region 360 of the shutter 330. The power of the second light L22 is lower than the power of the first light L21. For example, the first light L21 that has passed through the open region 350 of the shutter 330 may be provided to a portion of the warpage control layer 20, and the second light L22 that has passed through the non-open region 360 may be provided to the remaining portion of the warpage control layer 20. That is, the first light L21 that passes through the open region 350 of the shutter 330 may heat a portion of the warpage control layer 20 to a first temperature, and the second light L22 that passes through the non-open region 360 of the shutter 330 may heat the remaining portion of the warpage control layer 20 to a second temperature that is lower than the first temperature. As a result, a temperature difference may occur between the portion of the warpage control layer 20 heated to the first temperature and the remaining portion of the warpage control layer 20 heated to the second temperature. This temperature difference may be used to adjust the warpage of the wafer 10. For example, the warpage of the wafer 10 after completion of the annealing process may have a shape as shown in FIG. 15.

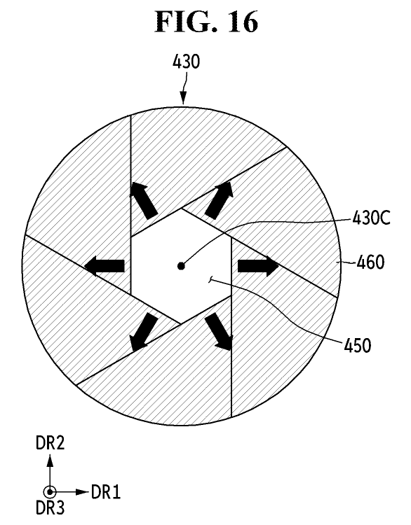

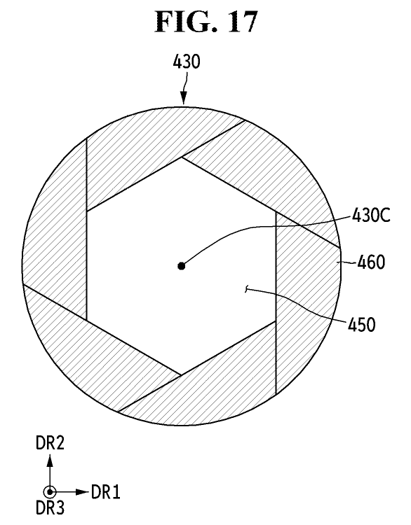

Hereinafter, a shutter of the heat treatment apparatus according to still other embodiments of the present disclosure will be described with reference to FIGS. 16 and 17. The description will focus on differences from the shutter of the heat treatment apparatus shown in FIGS. 2 and 3.

FIGS. 16 and 17 are diagrams for explaining a shutter of the heat treatment apparatus according to some other embodiments of the present disclosure.

Referring to FIGS. 16 and 17, in the heat treatment apparatus according to still other embodiments of the present disclosure, the diameter of the open region 450 of the shutter 430 may be adjustable.

For example, the shutter 430 may include an open region 450 and a non-open region 460. The width of the open region 450 of the shutter 430 in the first horizontal direction DR1 and the width of the open region 450 in the second horizontal direction DR2 may be adjusted simultaneously. Accordingly, the size of the open region 450 of the shutter 430 in the first horizontal direction DR1 and the size of the open region 450 of the shutter 430 in the second horizontal direction DR2 may be adjusted simultaneously. For example, the center 430C of the shutter 430 may be formed inside the open region 450 of the shutter 430. For example, the non-open region 460 of the shutter 430 may include a plurality of components that overlap with each other. For instance, the open region 450 of the shutter 430 may have a structure similar to that of a camera aperture.

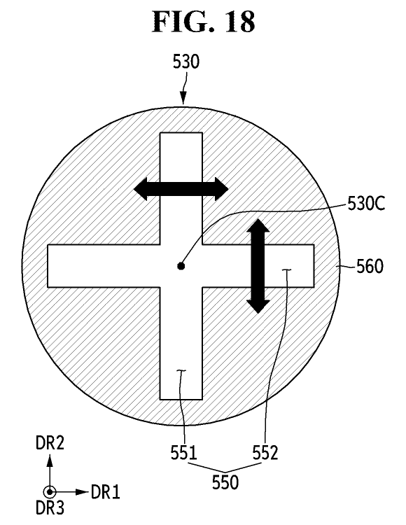

Hereinafter, a shutter of the heat treatment apparatus according to still other embodiments of the present disclosure will be described with reference to FIG. 18. The description will focus on differences from the shutter of the heat treatment apparatus shown in FIGS. 2 and 3.

FIG. 18 is a diagram for explaining a shutter of a heat treatment apparatus according to some other embodiments of the present disclosure.

Referring to FIG. 18, an open region 550 of a shutter 530 of the heat treatment apparatus according to still other embodiments of the present disclosure may include a first open region 551 and a second open region 552.

For example, the shutter 530 may include the open region 550 and a non-open region 560. The first open region 551 may extend in the second horizontal direction DR2. The first open region 551 may be adjustable in size in the first horizontal direction DR1. For example, the second open region 552 may extend in the first horizontal direction DR1. The second open region 552 may be adjustable in size in the second horizontal direction DR2. In some embodiments, to adjust the size of the open region 550, the size of either the first open region 551 or the second open region 552 may be adjusted. In other embodiments, to adjust the size of the open region 550, the sizes of both the first open region 551 and the second open region 552 may be adjusted simultaneously. For example, the first open region 551 and the second open region 552 may intersect at the center 530C of the shutter 530.

In some other embodiments, two or more shutters—such as the shutter 130 shown in FIGS. 2 and 3, the shutter 230 shown in FIGS. 9 and 10, the shutter 330 shown in FIGS. 11 and 12, the shutter 430 shown in FIGS. 16 and 17, and the shutter 530 shown in FIG. 18—may be stacked and used in the vertical direction DR3.

While the embodiments of the present disclosure have been described above with reference to the accompanying diagrams, it will be understood that the present disclosure is not limited to these embodiments, and may be implemented in various other forms. Those skilled in the art to which the present disclosure pertains will understand that the present disclosure may be implemented in other specific forms without changing the technical idea or essential features. Accordingly, the embodiments described above should be understood to be exemplary in all respects and not restrictive.

What is claimed is:

1. A method for fabricating a semiconductor device, the method comprising:
obtaining a warpage measurement information by measuring a warpage of a wafer;
forming a warpage control layer entirely on a lower surface of the wafer;
adjusting either a type of a shutter or a size of an open region of the shutter using the warpage measurement information, the shutter positioned below the wafer inside a chamber;
providing to the warpage control layer a light that is emitted from a light source and passes through the shutter; and
adjusting the warpage of the wafer by partially changing a temperature of the warpage control layer using the light provided to the warpage control layer,
wherein the shutter is positioned between the light source and the lower surface of the wafer, and
wherein each of the lower surface of the wafer and a lower surface of the warpage control layer is spaced apart from an upper surface of the shutter in a vertical direction.

2. The method of claim 1, wherein the adjusting of the warpage of the wafer by partially changing the temperature of the warpage control layer comprises:
determining whether the warpage of the wafer is within a predetermined range while the warpage of the wafer is being adjusted; and
stopping the emission of the light from the light source when the warpage of the wafer is within the predetermined range.

3. The method of claim 1, wherein the providing of the light that passes through the shutter to the warpage control layer comprises:
providing the light to a portion of the warpage control layer through the open region of the shutter, and not providing the light to a remaining portion of the warpage control layer overlapping with a non-open region of the shutter in the vertical direction.

4. The method of claim 3, wherein the adjusting of the warpage of the wafer by partially changing the temperature of the warpage control layer comprises:
heating a portion of the warpage control layer using the light; and
adjusting the warpage of the wafer by generating a temperature difference between the heated portion of the warpage control layer and a remaining unheated portion of the warpage control layer.

5. The method of claim 1, wherein the providing of the light that passes through the shutter to the warpage control layer comprises:
providing a first light that passes through the open region of the shutter to a portion of the warpage control layer; and
providing a second light that passes through the non-open region of the shutter to a remaining portion of the warpage control layer, the second light having lower power than the first light.

6. The method of claim 5, wherein the adjusting of the warpage of the wafer by partially changing the temperature of the warpage control layer comprises:
heating the portion of the warpage control layer to a first temperature using the first light, heating the remaining portion of the warpage control layer to a second temperature lower than the first temperature using the second light; and
adjusting the warpage of the wafer by generating a temperature difference between the portion of the warpage control layer heated to the first temperature and the remaining portion of the warpage control layer heated to the second temperature.

7. The method of claim 1, wherein the forming of the warpage control layer entirely on the lower surface of the wafer comprises:
loading the wafer having the warpage into the chamber; and
forming the warpage control layer entirely on the lower surface of the wafer inside the chamber.

8. The method of claim 1, wherein the forming of the warpage control layer entirely on the lower surface of the wafer comprises:
forming the warpage control layer entirely on the lower surface of the wafer having the warpage; and
loading the wafer formed the warpage control layer into the chamber.

9. The method of claim 1, wherein the adjusting of the size of the open region of the shutter comprises:
adjusting the size of the open region in a first horizontal direction parallel to the upper surface of the shutter.

10. The method of claim 9, wherein the adjusting of the size of the open region of the shutter further comprises:
adjusting the size of the open region in a second horizontal direction that is parallel to the upper surface of the shutter and perpendicular to the first horizontal direction.

11. The method of claim 1, wherein the shutter rotates in a plane parallel to the upper surface of the shutter.

12. A method for fabricating a semiconductor device, the method comprising:
forming a warpage control layer entirely on a lower surface of a wafer having a warpage;
adjusting a size of an open region of a shutter in a first horizontal direction parallel to an upper surface of the shutter, the shutter positioned below the wafer inside a chamber;
providing to the warpage control layer a light that is emitted from a light source and passes through the shutter;
adjusting the warpage of the wafer by partially changing a temperature of the warpage control layer using the light provided to the warpage control layer;
determining whether the warpage of the wafer is within a predetermined range while the warpage of the wafer is being adjusted; and
stopping the emission of the light from the light source when the warpage of the wafer is within the predetermined range,
wherein the shutter is positioned between the light source and the lower surface of the wafer.

13. The method of claim 12, wherein each of the lower surface of the wafer and a lower surface of the warpage control layer is spaced apart from the upper surface of the shutter in a vertical direction.

14. The method of claim 12, wherein the forming of the warpage control layer entirely on the lower surface of the wafer comprises:
loading the wafer having the warpage into the chamber; and
forming the warpage control layer entirely on the lower surface of the wafer inside the chamber.

15. The method of claim 12, wherein the forming of the warpage control layer entirely on the lower surface of the wafer comprises:
forming the warpage control layer entirely on the lower surface of the wafer having the warpage; and
loading the wafer formed the warpage control layer into the chamber.

16. The method of claim 12, wherein the open region extends in a second horizontal direction parallel to the upper surface of the shutter, and the second horizontal direction is perpendicular to the first horizontal direction.

17. The method of claim 12, wherein the shutter comprises the open region and a non-open region surrounding the open region, and
wherein the non-open region comprises a first portion forming an edge of the shutter and a second portion extending in the second horizontal direction between the first portions, the second horizontal direction is perpendicular to the first horizontal direction.

18. The method of claim 17, wherein the open region comprises:
a first open region formed on a first side of the second portion of the non-open region; and
a second open region formed on a second side of the second portion of the non-open region, which is opposite to the first side of the second portion of the non-open region in the first horizontal direction, and
wherein each of a size of the first open region and a size of the second open region is adjusted in the first horizontal direction.

19. The method of claim 12, wherein the open region comprises:
a first open region extending in a second horizontal direction, which is parallel to the upper surface of the shutter and perpendicular to the first horizontal direction, and a size of the first open region adjusting in the first horizontal direction; and
a second open region extending in the first horizontal direction, the second open region intersecting the first open region, and a size of the second open region adjusting in the second horizontal direction.

20. A method for fabricating a semiconductor device, the method comprising:
obtaining a warpage measurement information by measuring a warpage of a wafer;
loading the wafer having the warpage into a chamber;
forming a warpage control layer entirely on a lower surface of the wafer inside the chamber;
adjusting a size of an open region of a shutter in a first horizontal direction parallel to an upper surface of the shutter using the warpage measurement information, the shutter positioned below the wafer inside the chamber;
providing to the warpage control layer a light that is emitted from a light source and passes through the shutter;
adjusting the warpage of the wafer by partially changing a temperature of the warpage control layer using the light provided to the warpage control layer;
determining whether the warpage of the wafer is within a predetermined range while the warpage is being adjusted; and
stopping the emission of the light from the light source when the warpage of the wafer is within the predetermined range,
wherein the shutter is positioned between the light source and the lower surface of the wafer,
wherein each of the lower surface of the wafer and a lower surface of the warpage control layer is spaced apart from the upper surface of the shutter in a vertical direction, and
wherein the open region extends in a second horizontal direction parallel to the upper surface of the shutter, and the second horizontal direction is perpendicular to the first horizontal direction.
